(19) United States
(12) Patent Application Publication
(10) Pub. No.: US 2020/0160622 A1
(43) Pub. Date: May 21, 2020

(54) System and Method for Monitoring Battery Health

(71) Applicant: Solera Holdings, Inc., Westlake, UT (US)

(72) Inventors: Anthony Aquila, Westlake, TX (US); Joseph Thomas Mader, Southlake, TX (US); John Bono, Westlake, TX (US)

(21) Appl. No.: 16/682,785

(22) Filed: Nov. 13, 2019

Related U.S. Application Data
(60) Provisional application No. 62/767,861, filed on Nov. 15, 2018.

(51) Int. Cl. G07C 5/00; G07C 5/08; H04W 4/38; G08B 21/18; G01R 31/392; G01R 31/371; G01R 31/3835; G01R 31/367

(52) U.S. Cl. CPC G07C 5/008; G07C 5/0808; H04W 4/38; G01R 31/367; G01R 31/392; G01R 31/371; G01R 31/3835; G08B 21/182

(57) ABSTRACT

A system and method for battery health monitoring includes at least one sensor that reads at least voltage from one or more monitored batteries. Other metrics may optionally be monitored such as but not limited to, temperature, humidity, kinesis and the like. The system and method may display data to a local or remote user via a web portal or application, and transmit alarms and notifications via available technologies such as, but not limited to, short message services (SMS), email and other like messaging protocols.

### RELATED APPLICATION

This application claims the benefit, under 35 U.S.C. § 119(e), of U.S. Provisional Patent Application No. 62/767,861 filed 15 Nov. 2018, which is incorporated herein by reference.

### TECHNICAL FIELD

The disclosure generally relates to monitoring the health of batteries and more specifically to a semi-autonomous system and method for configuring, monitoring, and reporting on the health of batteries.

### BACKGROUND INFORMATION

Vehicle batteries such as those in an automobile, truck, maritime vessel, aircraft and the like, when left connected or not regularly operated for some length of time, often discharge or even become fully depleted, due to leakage current from the vehicle's electrical system. Depending on the extent of the discharge and other environmental variables, the affected battery may require a charge before it is again capable of performing its required functions within the vehicle into which it is installed. In many cases, the battery may become permanently damaged if drained below its state of full discharge. By way of example, a typical lead acid vehicle battery becomes damaged once its' capacity is depleted by twenty percent (20%), or to around ten and one-half (10.5) volts for a twelve (12) volt battery.

Discharged or damaged batteries may result in stranded drivers, late deliveries, unnecessary replacement costs, and significant environmental waste. This problem is particularly acute for entities such as vehicle dealerships, manufacturers, and vehicle transporters, that own or manage many vehicles that are often idle for prolonged periods of time (e.g. vehicles parked on dealership lots).

### SUMMARY

A system and method for battery health monitoring includes at least one sensor that reads at least voltage from one or more monitored batteries. Other metrics may optionally be monitored such as but not limited to, temperature, humidity, kinesis, and the like. The system and method may display data to a local or remote user via a web portal or application, and transmit alarms and notifications via available technologies such as, but not limited to, short message services (SMS), email, and other like messaging protocols.

The system and method may optionally include cellular wireless technologies to send monitoring data to remote users or a remote data processing service to overcome geographical spans outside of the range of local wireless services, such as Wi-Fi.

Other embodiments may include a cellular gateway that may receive, aggregate, and transmit data from multiple local sensors using alternative wireless technologies such as Wi-Fi, Bluetooth, or local range wireless.

### BRIEF DESCRIPTION OF THE DRAWINGS

For a more complete understanding of this disclosure and its features, reference is now made to the following description, taken in conjunction with the accompanying drawings, in which:

FIG. 1 is a general system level diagram of a battery health monitoring system practiced in accordance with principles of the present invention;

FIG. 2 is a block diagram of a sensor module practiced in accordance with principles of the present invention;

FIG. 3 is a block diagram of a sensor gateway practiced in accordance with principles of the present invention;

FIG. 4 is an exemplary embodiment for the battery health monitoring system for a remotely located vehicle practiced in accordance with principles of the present invention;

FIG. 5 is an exemplary embodiment for a battery health monitoring system at a car dealership practiced in accordance with principles of the present invention;

FIG. 6 is a swim lane diagram of the process flow in the battery health monitoring system in accordance with the principles of the present invention; and,

FIG. 7 depicts an exemplary but not exclusive computing device and mobile computer device which may be used to implement the processes described in FIG. 6.

### DETAILED DESCRIPTION

The FIGS. discussed below, and the various embodiments used to describe the principles in this document are by way of illustration only and should not be construed in any way to limit the scope of the invention. A person having ordinary skill in the art (“PHOSITA”) will understand that the principles may be implemented in any type of suitably arranged device or system.

Computer programs also referred herein as software, code, applications or “apps”, include machine instructions for a programmable processor, and can be implemented in a high-level procedural and/or object-oriented programming language, and/or in assembly/machine language. The terms “machine-readable medium” “computer-readable medium” refer to any computer program product, apparatus and/or device (e.g., magnetic discs, optical disks, memory, Programmable Logic Devices (PLDs)) used to provide machine instructions and/or data to a programmable processor, including a machine-readable medium that receives machine instructions as a machine-readable signal. The term “machine-readable signal” refers to any signal used to provide machine instructions and/or data to a programmable processor.

To provide for interaction with a user, the systems and techniques described here can be implemented on a device having a display (e.g., OLED/LCD monitor) for displaying information to the user and an input mechanisms (e.g. keyboard, pointing device, touch screen) by which the user can provide input to the device. Other kinds of mechanisms can be used to provide for interaction with a user as well; for example, feedback provided to the user can be any form of sensory feedback (e.g., visual feedback, auditory feedback, or tactile feedback); and input from the user can be received in any form, including acoustic, speech, or tactile input.

The system and techniques described herein can include a back end component (e.g., as a data processing server), or that includes a middleware component (e.g., an application server), or that includes a front end component (e.g., a client computer having a graphical user interface or a Web browser through which a user can interact with an implementation of the systems and techniques described herein), or any combination of such back end, middleware, or front end components. The components of the system can be interconnected by any form or medium of digital data communication (e.g., a communication network). Examples of communication networks include a local area network (“LAN”), a wide area network (“WAN”), cellular network and the Internet. The system can include clients and servers. A client and server are generally remote from each other and typically interact through a communication network. The relationship of client and server arises by virtue of computer programs running on the respective devices and having a client-server relationship to each other. The phrase “Application Programming Interface” (“API”) as used herein means a protocol for requesting services provided by computer programs or other software components.

The terms “communicate,” “transmit,” and “receive,” as well as derivatives thereof, encompasses both direct and indirect communication. The terms “include” and “comprise,” as well as derivatives thereof, mean inclusion without limitation. The term “or” is inclusive, meaning and/or. The phrase “associated with,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “at least one of,” when used with a list of items, means that different combinations of one or more of the listed items may be used, and only one item in the list may be needed. For example, “at least one of: A, B, and C” includes any of the following combinations: A, B, C; A and B; A and C; B and C; and A and B and C.

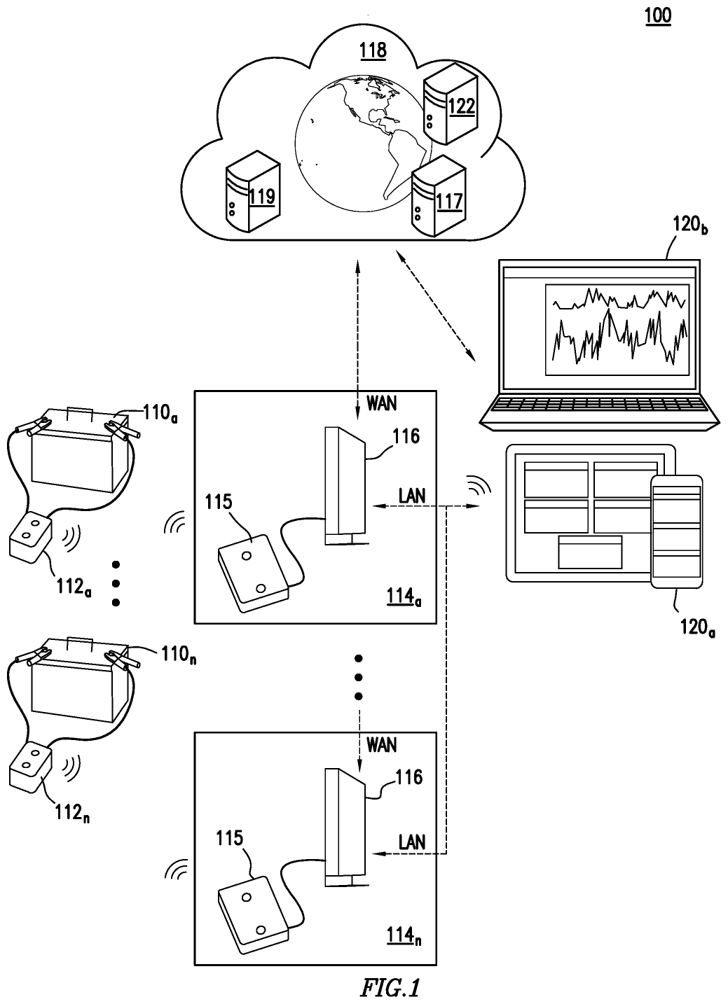

Reference is now made to FIG. 1 that illustrates an exemplary but not exclusive embodiment of a battery health monitoring system (“BHM system”) 100 practiced in accordance with the principles of the present invention. Batteries 110ₐ-110ₙ are installed in situ in vehicles (not shown), have respective sensor modules 112ₐ-112ₙ coupled across the respective positive and negative terminals of each battery 110ₐ-110ₙ. In other embodiments, sensor module 112 may be connected to the battery 110 via the electrical system of the vehicle such as through the On-Board Diagnostic II (OBDII) interface (not shown) or connected to the electrical system through the cigar lighter plug (not shown), accessory power port (not shown), or other power access location of the vehicle (not shown). When sensor modules 112ₐ-112ₙ are directly coupled across the positive and negative terminals of batteries 110ₐ-110ₙ, the load terminals of the respective vehicles (not shown) are preferably removed from batteries 110ₐ-110ₙ to avoid parasitic current drain.

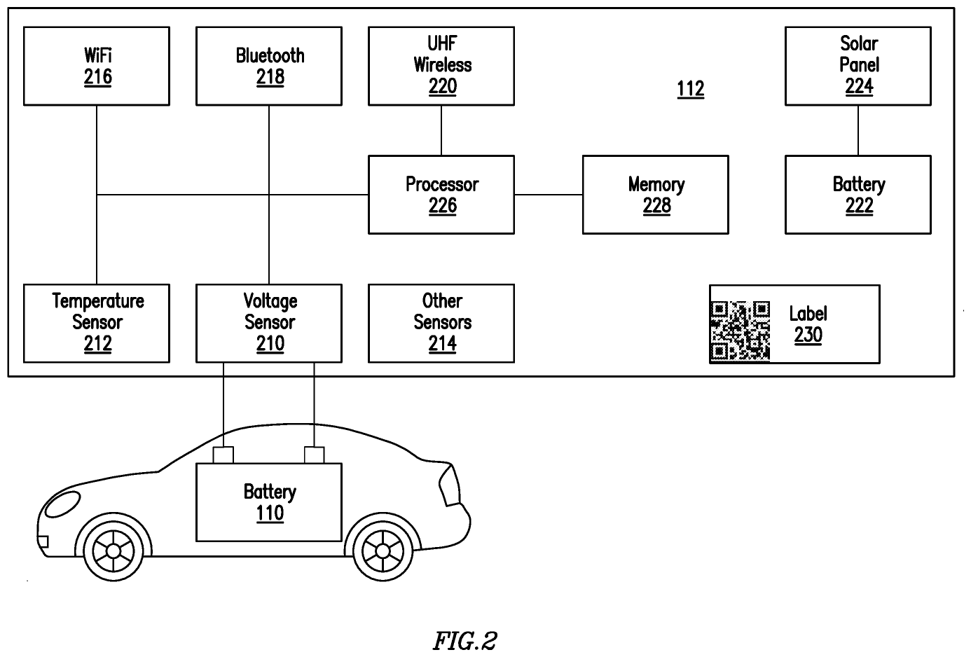

As described in more detail herein below and depicted in FIG. 2, sensor module 112 reads at least the voltage from the battery 110 at predetermined time intervals, upon certain predetermined events, or both, and may also read other optional types of sensor data such as ambient air temperature, humidity, kinesis and the like. As described in more detail hereinbelow, the sensor module 112 wirelessly sends this collective data to a sensor gateway 114 (depicted in FIG. 1). The sensor module 112 and gateway 114 are wirelessly coupled together—preferably by way of a low power protocol—which typically but not necessarily has a low bandwidth attribute. Exemplary but not exhaustive such protocols may include IEEE 802.15.4 (Zigbee), Z-Wave, Bluetooth LE “low energy”, and the like. As described in more detail hereinbelow, sensor module 112 may also be wirelessly coupled to the gateway 114 with other “higher speed” protocols such as, but not limited to, IEEE 802.11 (Wi-Fi), Bluetooth, or other local range wireless protocols. A PHOSITA will readily recognize many forms of wireless protocols for coupling the sensor module 112 to the sensor gateway 114 without departing from the spirit and scope of the present invention.

In one embodiment, the sensor gateway 114 includes a separately coupled local gateway 115 and network router 116. This connection may be—by way of example, a standard network protocol (e.g. 10/100/1000 ethernet).

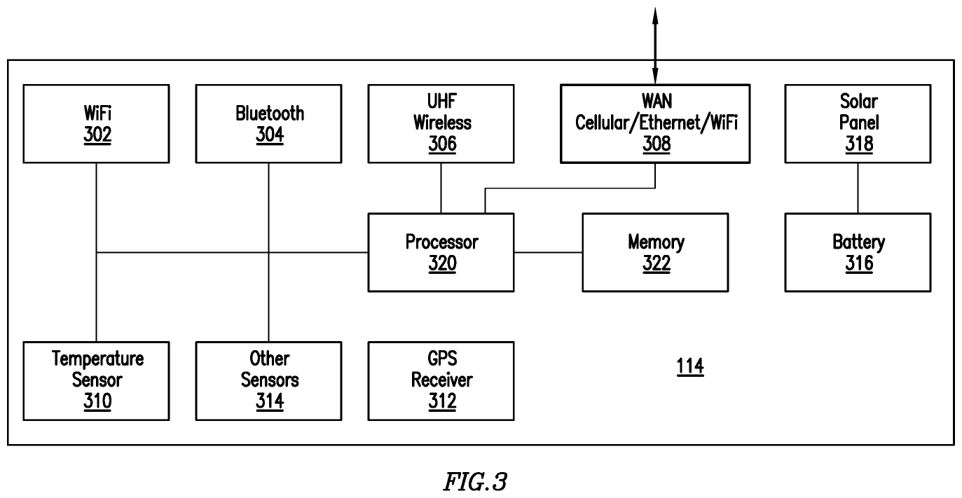

In another embodiment, the sensor gateway 114 unifies the local gateway 115 and router 116 functions as a single functional unit (see e.g. FIG. 3). The router 116 is preferably coupled to a wide area network (WAN) (e.g. the Internet) as well as coupled to provide local area network (LAN) wired and wireless connectivity.

Local gateway 115 typically has relatively limited geographical coverage for picking up signals from a sensor module 112. In large venues such a storage lot for vehicles (e.g. trucks or cars), multiple gateways 114 (depicted as 114ₐ-114ₙ in FIG. 1) are positioned such that seamless coverage across the venue is maintained. Overlap and prioritization for sensor module 112 and gateway 114 are described in more detail below.

A Remote Data Processing Server “RDPS” 117 manifests as a cloud based virtual machine 118 however a PHOSITA will recognize other embodiments such as a RDPS server device coupled to the LAN. Local clients 120a and/or remote clients 120b are coupled respectively to the RDPS 117. Gateway configuration server 119 also manifests as a cloud based virtual machine 118, however a PHOSITA will recognize other embodiments such as a gateway server device coupled to the LAN.

Referring now to FIG. 2, sensor module 112 includes voltage sensor 210 and may include temperature sensor 212, and other sensors 214 including but not limited to pressure, humidity, liquid, motion, kinesis (accelerometer), exposure (open/closed engine hood), start/stop (actuation counter), GPS, OBDII and the like. Sensor module 112 may also include one or more wireless interface technologies such as IEEE 802.11 Wi-Fi 216, Bluetooth 218, cellular and/or UHF local range wireless technology 220. Exemplary but not exclusive local range wireless technology is the 33-centimeter or 900 MHz band (902 to 928 MHz) 220 which is a portion of the UHF radio spectrum internationally allocated to amateur radio.

The sensor module 112 may be powered by the monitored battery 110 but preferably includes a built-in battery 222 (e.g. coin cell, or rechargeable battery), and/or optional solar cell panel 224 such that it does not place additional demand on the battery 110 being monitored. Additionally, the sensor module 112 preferably includes a processor 226 and memory 228 to control the activities of the sensor module 112. Each sensor module 112 may include a label 230 to provide a unique identification number or code. The identification code provided by label 230 may be displayed in a human readable format, as well as in the form of a machine-readable code such as a QR code, bar code, or RFID readable label.

Referring now to FIG. 3, an embodiment of the sensor gateway 114 is depicted for receiving data from one or more of multiple sensors 112ₐ-112ₙ using alternative wireless technologies such as Wi-Fi 302, Bluetooth 304, and/or local range UHF wireless 306. Gateway 114 includes processor 320 and memory 322 for among other things, to aggregate and transmit data using a WAN data-connected interface 308 such as but not limited to, cellular, ethernet, or Wi-Fi.

Sensor gateway 114 may also include a GPS receiver 312 and one or more other sensors, such as a temperature sensor 310 and other sensors 314 such as but not limited to humidity, liquid, motion, kinesis (accelerometer), and the like. The additional data provided by GPS receiver 312, temperature sensor 310, and other sensors 314 may be used to ascertain the location and/or environmental conditions for all sensor-equipped vehicles within the local range of gateway 114. Local environmental conditions, such as ambient air temperature directly affects the voltage of a typical lead-acid vehicle battery. For example, as temperatures decline, a battery's output voltage will drop. Therefore, ambient temperature may be a correlator for compensating for fluctuations in a battery's voltage. Gateway 114 may include an internal battery 316 and/or solar panel 318 to power sensors 310, 312, and 314 in lieu of a local wired power source, or in cases of a temporary power outage.

In some embodiments, sensor gateway 114 may be configured to receive configuration data, or provide diagnostic information from/to an application “app” running on local client 120a and/or remote client 120b or from portal 122 (described in more detail hereinbelow) via a wireless technology (such as Bluetooth, Wi-Fi, etc.) or a WAN connected interface such as Ethernet or Wi-Fi.

The gateway configuration server 119 (FIG. 1) configured as a cloud based virtual machine 118, is coupled to sensor gateway 114 to facilitate system configuration. Alternative embodiments include the gateway configuration server 119 manifested as hardware coupled to the LAN.

Certain embodiments and configurations of sensor module 112 may transmit data over its wireless interface to sensor gateway 114 without regard to addressing schemes and/or security. For security and device management, the associated gateway 114 has a need to know which sensor module 112 from which it is authorized to receive data. Gateway configuration server 119 maintains a database of all sensor modules 112 that are allocated to a particular gateway 114. As described in more detail hereinbelow, the database may be updated by user actions within an app running on a client device 120 or through a portal 122 which may manifest as a cloud based virtual machine 118. Each participating gateway 114 may retrieve its list of allocated sensor modules 112 from the database maintained by gateway configuration server 119 based on pre-determined update intervals, or upon certain events, such as a change notification message from the RDPS 117.

In an embodiment, an app may be used to facilitate sensor module 112 installation or monitoring. The app may run on any client 120 e.g. smartphone, tablet, or other computing device. The app preferably provides the ability to scan or manually enter the Vehicle Identification Number (VIN) of a monitored vehicle along with the identification code of its associated sensor module 112. The sensor's 112 identification code may be determined by reading its label 230 or via identifiers routinely transmitted by one or more of its wireless interfaces, such as NFC, WiFi, Bluetooth, etc. Moreover, the app may use data from sensors within the client computing device 120 to attain additional data regarding the location of the sensor module 112 and the environment at the time of sensor module 112 installation. For example, app may capture computing device 120 data such as current time, GPS location, available wireless networks, computing device identifiers (including user, device type, and software versions), current temperature, vehicle/environment images, RFID data, etc.)

In some embodiments, the app running on client computing device 120 may connect directly to sensor module 112 using a wireless technology (such as Bluetooth, Wi-Fi, etc.) to configure, provision, or perform diagnostics on the sensor module 112.

Cloud-based Portal 122 may be used by individuals to visualize data collected from sensor modules 112ₐ-112ₙ. For example, a user could view real-time or historical sensor data from equipped vehicles, assign sensor modules 112 to specific vehicles and gateways 114, and provision alerts and notifications.

The RDPS 117 is the primary point of data processing and database storage for the BHM System 100. RDPS 117 might also read local weather forecast data from publicly available weather services. This would enable the BHM system 100 to predict expected voltage drops due to temperature changes well in advance so that affected batteries could be preventively charged to avoid future alarms or risk of battery damage.

The variety of included wireless technologies provide flexibility for sensor module 112 to be used in multiple single sensor environments or a single environment with multiple sensors.

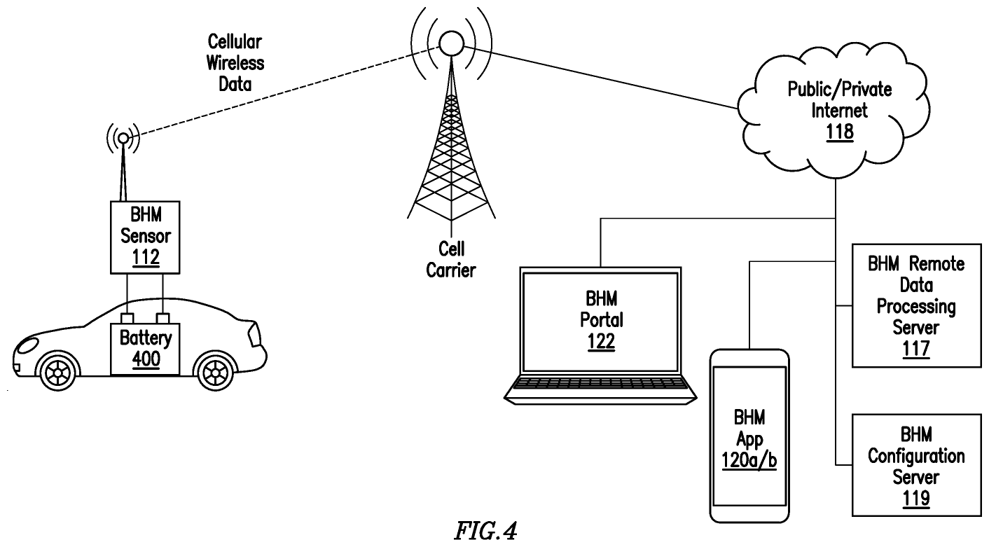

Reference is now made to FIG. 4 which depicts an exemplary embodiment for the battery health monitoring system for a remotely located vehicle 400 practiced in accordance with principles of the present invention. The sensor module 112 employs cellular connectivity to the cloud based virtual machine 118. However, a cellular-based solution may be too expensive for a large vehicle dealership.

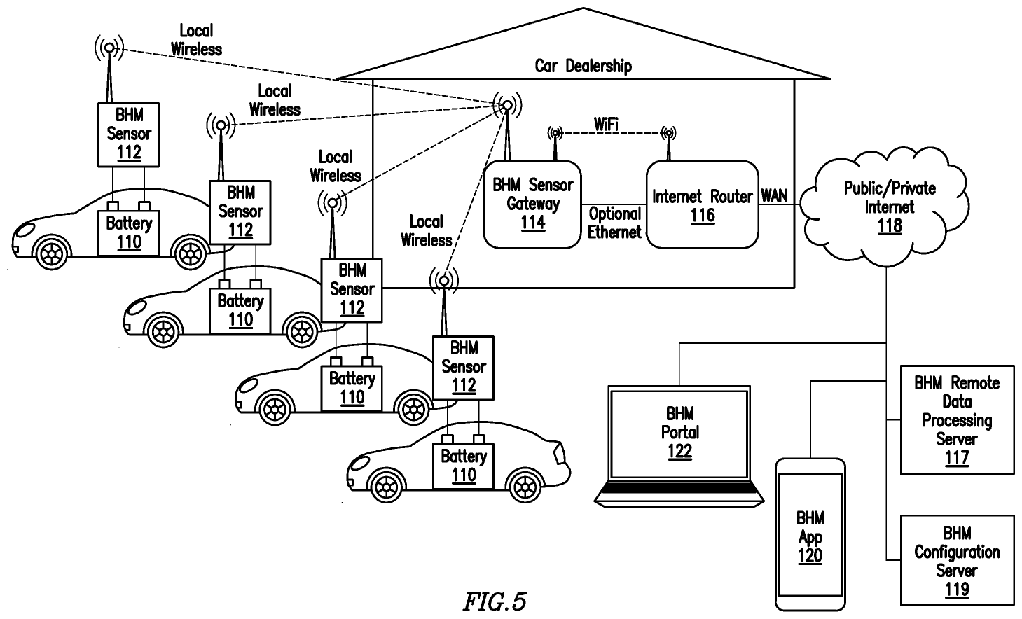

Reference is now made to FIG. 5 which depicts an exemplary embodiment for a battery health monitoring system at a car dealership practiced in accordance with principles of the present invention. The dealership would prefer to use a no-cost/low-cost local wireless technology, such as 900 MHz UHF radio spectrum to capture and aggregate sensor data from all vehicles on a given lot through gateway devices 116 to upload via the WAN local internet access or cellular data link.

To reduce leakage current from a vehicle battery and significantly slow idle battery drain, a technician is encouraged, but not mandated, to disconnect the electrical load terminals from the battery 110 when installing sensor module 112. At the time of sensor module 112 installation, the technician may use an app running on a client device 120 to scan vehicle identifiers (e.g. VIN, license plate, DOT, etc.) and sensor module identifiers 230 (e.g. barcode, device id, etc.). The app transmits this information, along with other data from the computing device 120 (e.g. GPS, time, temperature, etc.), and any manually entered or selected data from within the app (e.g. selected gateway 114, technician name/ID, etc.) to the BHM System 100 including at least one Application Programming Interface (API). The BHM System 100 binds the vehicle in a database and sends update instructions (encrypted, TCP) to the gateway configuration server 119 which configures the appropriate gateway 116. The selected gateway will now listen for data transmissions from the newly added sensor module 112.

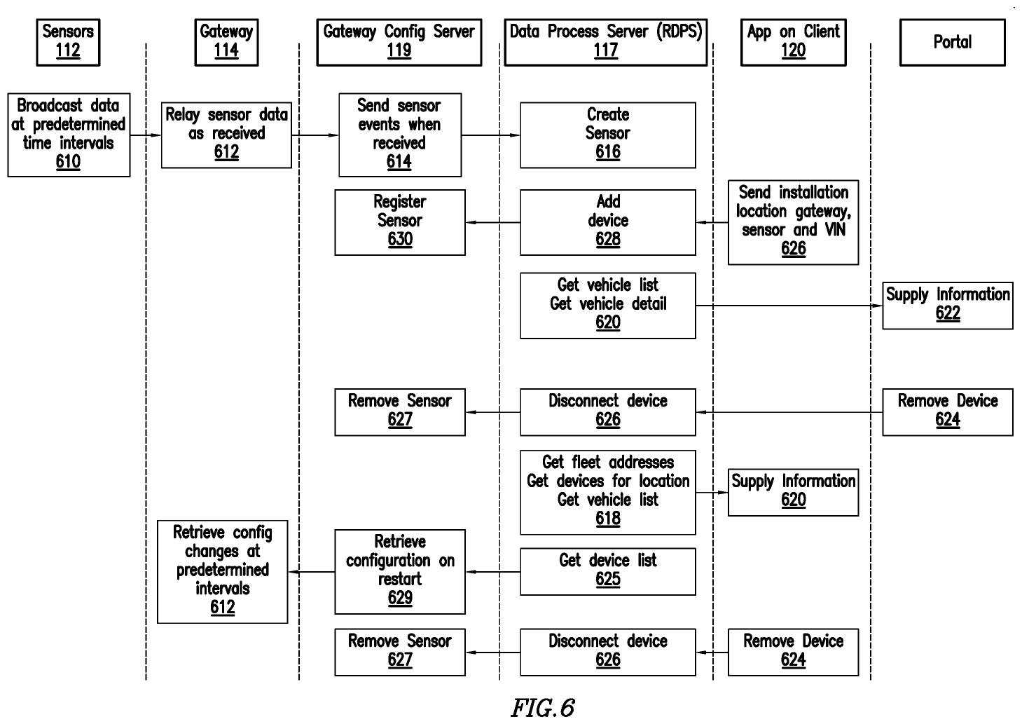

Reference is now made to FIG. 6 depicting a swim lane diagram of the process flow in the BHM system 100. It is to be understood that the vertical lanes represent the processes performed by the identified devices and that the processes are not necessarily dependent or sequential. At step 625, the RDPS 117 gets the device list by retrieving the configuration on restart from the gateway configuration server 117 at step 629. The sensor module gateway 114 retrieves configuration changes at predetermined time intervals from configuration server 119 at step 631.

At step 626, an app running on a client device 120 sends information for installation location, gateway sensor, and VIN information to the RDPS 117 to add/associate a device at step 628 in the RDPS 117. Gateway configuration server 119 in turn registers/associates a sensor module 112 with a particular vehicle's VIN at step 630.

At step 610, upon expiry of a preprogrammed period, or other event, each sensor module 112 wakes, captures battery voltage and other optional sensor data, broadcasts the data via one or more of its wireless interfaces, and then returns to sleep. This preserves the life of each BHM sensor battery 222.

As described in more detail hereinbelow, the gateway 114 is configured to listen for a predetermined sensor module 112 and at step 614, gateway receives the sensor module broadcast and relays the received data to the gateway configuration server 119. The transmission protocol is preferably encrypted and by way of cellular but could be Wi-Fi, wired ethernet and the like. At step 614, gateway configuration server 119 creates a sensor entry and the RDPS 117 stores the BHM sensor event in its database at step 616. At steps 618 and 620, RDPS 117 aggregates, analyzes, and prepares a sensor data report, and sends the report preferably as encrypted HTTPS to fleet managers for example, but other interested parties, to an app on the client 120 at step 620 and through the Web Portal at step 622. Additionally, RDPS can notify interested parties by sending emails, text messages and the like. This flow repeats until some link in the chain is broken (BHM sensor module 112 is turned off, a request from the portal at step 624 to decouple at step 626 in the RDPS, unregister in gateway configuration server 119 at step 627, the gateway 114 is turned off and the like. It is to be understood that steps 624, 626 and 627 may be omitted (or included) without departing from the scope of the invention.

The Portal displays a list of vehicles with BHM sensors 112a-112n attached. The list may be sorted and/or filtered by battery voltage level, vehicle age, battery age, installation date, geographic location, temperature, climate, severe weather, etc. An exemplary embodiment of the BHM Portal would also include automatic alarms and notifications to alert concerned individuals when any vehicle's battery has discharged to certain thresholds. The methodology used to transmit such alarms or notifications could include SMS messages, in-app alerts, phone calls, emails, etc. These notification or alarms could be used, for example, by a car dealership manager to dispatch a technician to charge a battery before the vehicle can't start, or the battery is damaged. In some embodiments, alarms and notifications regarding a vehicle's battery may be filtered with atmospheric data (e.g., temperature). For example, if a certain vehicle's battery has discharged below a certain level, but the ambient temperature for the battery is lower than a certain threshold, an alarm or notification for the battery may be delayed or otherwise canceled until the ambient temperature rises above the threshold. In this scenario, if the vehicle's battery is still below a certain level even after the ambient temperature rises above the threshold, an alarm or notification may be sent to alert concerned individuals about the vehicle's battery.

The Portal further provides users with the ability to disconnect the BHM sensor module 112 from the vehicle (decouple the database pairing and configure the gateway to unregister the sensor module 112). The BHM Portal could also be used to quickly enter binding information to pre-allocate a specific sensor module 112 with individual vehicles, or specific gateways 114 with certain locations, facilities, customers, etc.)

The BHM Portal may also be used to provide use-case specific functions. For example, a car dealership may desire to have the BHM Portal automatically produce a check-in/check-out report that details the state of the battery at time of vehicle intake, event history (alarms, notifications, interventions) during monitoring period, and battery state at time of departure. Additional detail such as environmental variables, experienced during the monitoring period could be included in the report.

Alerts to users via email, text, phone, app notification, web notification, etc. may be triggered when a flag is raised or a threshold crossed or some event occurs such as but not limited to: battery is low, battery is depleted, battery has been dropped, battery has been agitated, temperature drops suddenly, temperature spikes suddenly, severe weather imminent, and the like.

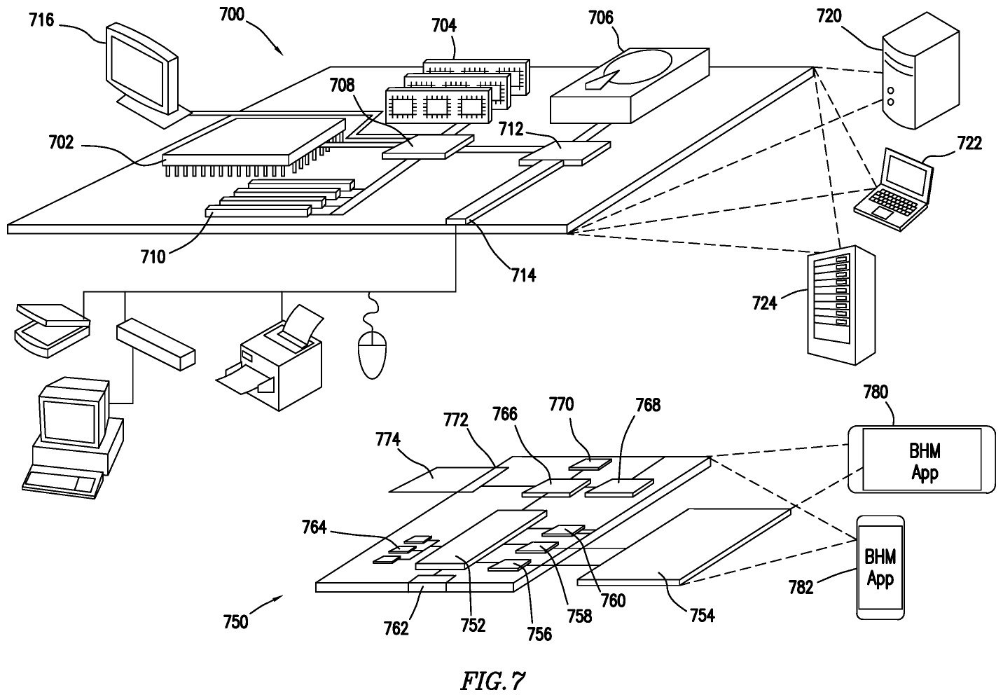

FIG. 7 depicts an exemplary but not exclusive computing device 700 and mobile computer device 750, which may be used to implement the processes described herein, including the mobile-side and server-side processes for installing a computer program from a mobile device to a computer. Computing device 700 is intended to represent various forms of digital computers, such as laptops, desktops, workstations, personal digital assistants, servers, blade servers, mainframes, and other appropriate computers. Computing device 750 is intended to represent various forms of mobile devices, such as personal digital assistants, cellular telephones, smartphones, and other similar computing devices. The components shown here, their connections and relationships, and their functions, are meant to be exemplary only, and are not meant to limit implementations of the inventions described and/or claimed in this document.

Computing device 700 includes a processor 702, memory 704, a storage device 706, a high-speed interface 708 connecting to memory 704 and high-speed expansion ports 710, and a low speed interface 712 connecting to low speed bus 714 and storage device 706. Each of the components 702, 704, 706, 708, 710, and 712 are interconnected using various busses, and may be mounted on a common motherboard or in other manners as appropriate. The processor 702 can process instructions for execution within the computing device 700, including instructions stored in the memory 704 or on the storage device 706 to display graphical information for a GUI on an external input/output device, such as display 716 coupled to high speed interface 708. In other implementations, multiple processors and/or multiple busses may be used, as appropriate, along with multiple memories and types of memory. Also, multiple computing devices 700 may be connected, with each device providing portions of the necessary operations (e.g., as a server bank, a group of blade servers, or a multi-processor system).

The memory 704 stores information within the computing device 700. In one implementation, the memory 704 is a volatile memory unit or units. In another implementation, the memory 704 is a non-volatile memory unit or units. The memory 704 may also be another form of computer-readable medium, such as a magnetic or optical disk.

The storage device 706 is capable of providing mass storage for the computing device 700. In one implementation, the storage device 706 may be or contain a computer-readable medium, such as a floppy disk device, a hard disk device, an optical disk device, or a tape device, a flash memory or other similar solid state memory device, or an array of devices, including devices in a storage area network or other configurations. A computer program product can be tangibly embodied in an information carrier. The computer program product may also contain instructions that, when executed, perform one or more methods, such as those described above. The information carrier may be a non-transitory computer- or machine-readable storage medium, such as the memory 704, the storage device 706, or memory on processor 702.

The high speed controller 708 manages bandwidth-intensive operations for the computing device 700, while the low speed controller 712 manages lower bandwidth-intensive operations. Such allocation of functions is exemplary only. In one implementation, the high-speed controller 708 is coupled to memory 704, display 716 (e.g., through a graphics processor or accelerator), and to high-speed expansion ports 710, which may accept various expansion cards (not shown). In the implementation, low-speed controller 712 is coupled to storage device 706 and low-speed expansion port. The low-speed expansion port which may include various communication ports (e.g., USB, Bluetooth, Ethernet, wireless Ethernet), may be coupled to one or more input/output devices, such as a keyboard, a pointing device, a scanner, or a networking device such as a switch or router, e.g., through a network adapter.

The computing device 700 may be implemented in a number of different forms, as shown in FIG. 7. For example, it may be implemented as a standard server 720, or multiple times in a group of such servers. It may also be implemented as part of a rack server system 724. In addition, it may be implemented in a personal computer such as a laptop computer 722. Alternatively, components from computing device 700 may be combined with other components in a mobile device (not shown), such as device 750. Each of such devices may contain one or more of computing device 700, 750, and an entire system may be made up of multiple computing devices 700, 750 communicating with each other.

Computing device 750 includes a processor 752, memory 764, an input/output device such as a display 754, a communication interface 766, and a transceiver 768, among other components. The device 750 may also be provided with a storage device, such as a microdrive or other device, to provide additional storage. Each of the components 750, 752, 764, 754, 766, and 768 are interconnected using various busses, and several of the components may be mounted on a common motherboard or in other manners as appropriate.

The processor 752 can execute instructions within the computing device X50, including instructions stored in the memory 764. The processor may be implemented as a chipset of chips that include separate and multiple analog and digital processors. The processor may provide, for example, for coordination of the other components of the device 750, such as control of user interfaces, applications run by device 750, and wireless communication by device 750.

Processor 752 may communicate with a user through control interface 758 and display interface 756 coupled to a display 754. The display 754 may be, for example, a TFT LCD (Thin-Film-Transistor Liquid Crystal Display) or an OLED (Organic Light Emitting Diode) display, or other appropriate display technology. The display interface 756 may comprise appropriate circuitry for driving the display 754 to present graphical and other information to a user. The control interface 758 may receive commands from a user and convert them for submission to the processor 752. In addition, an external interface 762 may be provided in communication with processor 752, so as to enable near area communication of device 750 with other devices. External interface 762 may provide, for example, for wired communication in some implementations, or for wireless communication in other implementations, and multiple interfaces may also be used.

The memory 764 stores information within the computing device 750. The memory 764 can be implemented as one or more of a computer-readable medium or media, a volatile memory unit or units, or a non-volatile memory unit or units. Expansion memory 774 may also be provided and connected to device 750 through expansion interface 772, which may include, for example, a SIMM (Single In Line Memory Module) card interface. Such expansion memory 774 may provide extra storage space for device 750, or may also store applications or other information for device 750. Specifically, expansion memory 774 may include instructions to carry out or supplement the processes described above, and may include secure information also. Thus, for example, expansion memory 774 may be provide as a security module for device 750, and may be programmed with instructions that permit secure use of device 750. In addition, secure applications may be provided via the SIMM cards, along with additional information, such as placing identifying information on the SIMM card in a non-hackable manner.

The memory may include, for example, flash memory and/or NVRAM memory, as discussed below. In one implementation, a computer program product is tangibly embodied in an information carrier. The computer program product contains instructions that, when executed, perform one or more methods, such as those described above. The information carrier is a computer- or machine-readable medium, such as the memory 764, expansion memory 774, memory on processor 752, or a propagated signal that may be received, for example, over transceiver 768 or external interface 762.

Device 750 may communicate wirelessly through communication interface 766, which may include digital signal processing circuitry where necessary. Communication interface 766 may provide for communications under various modes or protocols, such as GSM voice calls, SMS, EMS, or MIMS messaging, CDMA, TDMA, PDC, WCDMA, CDMA2000, GPRS, LTE, or 5G among others. Such communication may occur, for example, through radio-frequency transceiver 768. In addition, short-range communication may occur, such as using a Bluetooth, Wi-Fi, or other such transceiver (not shown). In addition, GPS (Global Positioning System) receiver module 770 may provide additional navigation- and location-related wireless data to device 750, which may be used as appropriate by applications running on device 750.

Device 750 may also communicate audibly using audio codec 760, which may receive spoken information from a user and convert it to usable digital information. Audio codec 760 may likewise generate audible sound for a user, such as through a speaker, e.g., in a handset of device 750. Such sound may include sound from voice telephone calls, may include recorded sound (e.g., voice messages, music files, etc.) and may also include sound generated by applications operating on device 750.

The computing device 750 may be implemented in a number of different forms, as shown in FIG. 7. For example, it may be implemented as a tablet 780, smartphone 782, personal digital assistant, or other similar mobile device.

Various implementations of the systems and techniques described here can be realized in digital electronic circuitry, integrated circuitry, specially designed ASICs (application specific integrated circuits), computer hardware, firmware, software, and/or combinations thereof. These various implementations can include implementation in one or more computer programs that are executable and/or interpretable on a programmable system including at least one programmable processor, which may be special or general purpose, coupled to receive data and instructions from, and to transmit data and instructions to, a storage system, at least one input device, and at least one output device.

A number of implementations have been described. Nevertheless, it will be understood that various modifications may be made without departing from the spirit and scope of the invention.

In addition, the logic flows depicted in the FIGS. do not require the particular order shown, or sequential order, to achieve desirable results. In addition, other steps may be provided, or steps may be eliminated, from the described flows, and other components may be added to, or removed from, the described systems. Accordingly, other implementations are within the scope of the following claims.

Elements of different implementations described herein may be combined to form other implementations not specifically set forth above. Elements may be left out of the processes, computer programs, Web pages, etc. described herein without adversely affecting their operation. Furthermore, various separate elements may be combined into one or more individual elements to perform the functions described herein.

While certain exemplary embodiments have been described and shown in the accompanying drawings, it is to be understood that such embodiments are merely illustrative of and not restrictive on the broad invention, and that this invention not be limited to the specific constructions and arrangements shown and described, since various other modifications may occur to those ordinarily skilled in the art.

What is claimed is:

1. A battery health monitoring system comprising:
at least one sensor communicatively coupled to a battery;
a sensor gateway configured to receive data from the at least one sensor;
a gateway configuration server communicatively coupled to the sensor gateway;
a data processing server communicatively coupled to the gateway configuration server; and
a client device communicatively coupled to the data processing server.

2. The battery health monitoring system of claim 1, wherein the at least one sensor is communicatively coupled to the battery via:
an On-Board Diagnostic (OBD) interface of a vehicle;
a lighter plug of the vehicle; or
an accessory power port of the vehicle.

3. The battery health monitoring system of claim 1, wherein the at least one sensor is operable to:
read a voltage of the battery; and
wirelessly transmit the read voltage of the battery to the sensor gateway.

4. The battery health monitoring system of claim 3, wherein the at least one sensor reads the voltage of the battery at predetermined time intervals.

5. The battery health monitoring system of claim 3, wherein the at least one sensor wirelessly transmits the read voltage of the battery to the sensor gateway using a low-power communications protocol, the low-power communications protocol comprising:
IEEE 802.15.4;
Z-Wave; or
Bluetooth low energy (LE).

6. The battery health monitoring system of claim 1, wherein the data processing server is operable to:
receive battery voltage information from the at least one sensor;
store the received battery voltage information in a database;
generate a sensor data report using at least the received battery voltage information; and
provide the sensor data report for display on the client device.

7. The battery health monitoring system of claim 1, further comprising a cloud-based portal operable to provide an alert based on battery voltage information from the at least one sensor.

8. A method of monitoring battery health comprising:
reading at least voltage data from a battery with at least one sensor;
receiving data from the at least one sensor into a sensor gateway;
configuring the sensor gateway with a gateway configuration server;
aggregate, analyze, and prepare a sensor data report with a data processing server; and
executing an app on a client device coupled to the data processing server.

9. The method of monitoring battery health of claim 8, wherein the at least one sensor is communicatively coupled to the battery via:
an On-Board Diagnostic (OBD) interface of a vehicle;
a lighter plug of the vehicle; or
an accessory power port of the vehicle.

10. The method of monitoring battery health of claim 8, further comprising wirelessly transmitting, by the at least one sensor, the voltage data to the sensor gateway.

11. The method of monitoring battery health of claim 10, wherein wirelessly transmitting the voltage data to the sensor gateway comprises using a low-power communications protocol, the low-power communications protocol comprising:
IEEE 802.15.4;
Z-Wave; or
Bluetooth low energy (LE).

12. The method of monitoring battery health of claim 8, wherein reading the voltage data from the battery comprises reading the voltage data from the battery at predetermined time intervals.

13. The method of monitoring battery health of claim 8, further comprising providing the sensor data report for display on the client device.

14. The method of monitoring battery health of claim 8, further comprising providing, by a cloud-based portal, an alert based on the voltage data from the battery.

15. An apparatus configured to communicatively couple to a vehicle battery, the sensor comprising:
a voltage sensor;
a communications interface;
one or more memory devices; and
a processor communicatively coupled to the one or more memory devices, the processor operable to:
wake the apparatus from a low-power sleep state upon expiry of a preprogrammed time period;
capture voltage data from the vehicle battery using the voltage sensor;
transmit the captured voltage data to a sensor gateway using the communications interface; and
return the apparatus to the low-power sleep state after transmitting the captured voltage data to the sensor gateway.

16. The apparatus of claim 15, wherein the apparatus is communicatively coupled to the battery via:
an On-Board Diagnostic (OBD) interface of the vehicle;
a lighter plug of the vehicle; or
an accessory power port of the vehicle.

17. The apparatus of claim 15, wherein transmitting the captured voltage data to the sensor gateway using the communications interface comprises wireless communications.

18. The apparatus of claim 17, wherein the wireless communications comprises:
IEEE 802.15.4;
Z-Wave; or
Bluetooth low energy (LE).

19. The apparatus of claim 15, further comprising a temperature sensor.

20. The apparatus of claim 19, wherein the processor is further operable to transmit, to the sensor gateway using the communications interface, an ambient temperature captured by the temperature sensor.
